(19) United States
(12) Patent Application Publication
(10) Pub. No.: US 2025/0030202 A1
(43) Pub. Date: Jan. 23, 2025

(54) ELECTRONIC SYSTEM ASSEMBLY FOR ELECTROMAGNETIC INTERFERENCE REDUCTION AND ELECTRICAL ARCING PROTECTION

(71) Applicant: Epirus, Inc., Torrance, CA (US)

(72) Inventors: Joseph Shin, Orange, CA (US); Anne Kimberly Granados Edquilang, Redondo Beach, CA (US); Alexander Paul Scott, Redondo Beach, CA (US); Han Wen Lin, Torrance, CA (US); Kiran Raj, San Diego, CA (US); Peter Todd Catalfamo, Redondo Beach, CA (US)

(21) Appl. No.: 18/777,401

(22) Filed: Jul. 18, 2024

Related U.S. Application Data
(60) Provisional application No. 63/514,950, filed on Jul. 21, 2023.

(51) Int. Cl. H01R 13/6594; H01R 12/71; H05K 1/18

(52) U.S. Cl. CPC H01R 13/6594; H01R 12/716; H05K 1/181; H05K 2201/10189; H05K 2201/10371

(57) ABSTRACT

Implementations of the present disclosure include an electronic system assembly including a first circuit board including a first set of electronic components. The electronic system assembly includes a first housing containing the first circuit board and a second circuit board including a second set of electronic components. The electronic system assembly further includes a first connector shield having first sidewalls defining a first cavity, the first sidewalls having a first end abutting a first surface of the first circuit board and a second end abutting a second surface of the second circuit board. A first electrical connection extends through the first cavity and electrically coupling the first set of electronic components with the second set of electronic components.

### CROSS-REFERENCE TO RELATED APPLICATIONS

This application claims priority to U.S. Provisional Application No. 63/514,950, filed Jul. 21, 2023, which is incorporated by reference in its entirety.

### TECHNICAL FIELD

The present disclosure relates to electronic system assemblies and, more particularly, to assemblies of electronic systems that include a plurality of subassemblies.

### BACKGROUND

Some electronics, during operation, may be sensitive to electromagnetic interference (EMI). It can be a difficult challenge to isolate such sensitive electronics from EMI emitted by other nearby electronics.

### SUMMARY

Disclosed herein are novel aspects of an electronic system and electronic system assembly. The electronic system assembly comprises a first circuit board including a first set of electronic components; a first housing containing the first circuit board; a second circuit board including a second set of electronic components; a first connector shield having first sidewalls defining a first cavity, the first sidewalls having a first end abutting a first surface of the first circuit board and a second end abutting a second surface of the second circuit board; and a first electrical connection extending through the first cavity and electrically coupling the first set of electronic components with the second set of electronic components.

In some implementations, the first connector shield includes a first gasket positioned on the first end and compressed against the first surface and the first connector shield including a second gasket positioned on the second end and compressed against the second surface. In some implementations, the first gasket and the second gasket include an elastically deformable material and an electrically conductive material. In some implementations, the first electrical connection includes a set of pins engaged with a set of receptacles.

In some implementations, the first set of electronic components are part of a first circuit on the first circuit board and the second set of electronic components are part of a second circuit on the second circuit board, and wherein the first circuit operates at a first power level and the second circuit operates at a second power level lower than the first power level, the first connector shield reducing electromagnetic interference coupling from the first circuit into the second circuit. In some implementations, the first circuit is a Radio Frequency circuit and the second circuit is a power converter circuit.

In some implementations, the first connector shield includes a flange and one or more apertures extending through the apertures, the first connector shield attached to the first housing via the one or more apertures.

In some implementations, the electronic system assembly comprises a third circuit board including a third set of electronic components; and a second housing containing the third circuit board, the second housing attached to the first housing and enclosing the second circuit board between the first housing and the second housing. In some implementations, the second circuit board includes a fourth set of electronic components and the electronic system assembly further comprises a second connector shield having second sidewalls defining a second cavity, the second sidewalls having a third end abutting a third surface of the second circuit board and a fourth end abutting a fourth surface of the third circuit board, the third surface opposite to the second surface; and a second electrical connection extending through the second cavity and electrically coupling the third set of electronic components with the fourth set of electronic components.

In some implementations, the second connector shield includes a third gasket positioned on the third end and compressed against the third surface and the second connector shield including a fourth gasket positioned on the fourth end and compressed against the fourth surface. In some implementations, the second circuit board includes an electrical connector exposed on an exterior of the electronic system assembly between the first housing and the second housing.

In some implementations, the electronic system assembly comprises a first port exposed on an exterior of the first housing, the first port electrically coupled to the first set of electronic components; a second housing having a bottom surface and sidewalls extending upwardly from the bottom surface; a second port exposed on an exterior of the second housing, the second port electrically coupled to the first port; a third circuit board attached to the bottom surface, the third circuit board including an electronic component and a first conductor on a surface of the third circuit board, the first conductor electrically coupled to the electronic component and the second port; and an electrically insulating material completely covering the first conductor. In some implementations, the electrically insulating material includes a silicone. In some implementations, the electrically insulating material at least partially covers the electronic component.

Implementations of the present disclosure include a system, comprising an electronic system configured to generate a set of electronic signals; an interface including a plurality of connectors arranged along a surface of the interface, the interface electrically coupled to the electronic system; and an electronic system assembly. The electronic system assembly of the system comprises a first circuit board including a first set of electronic components; a first housing containing the first circuit board; a second circuit board including a second set of electronic components; a first connector shield having first sidewalls defining a first cavity, the first sidewalls having a first end abutting a first surface of the first circuit board and a second end abutting a second surface of the second circuit board; a first electrical connection extending through the first cavity and electrically coupling the first set of electronic components with the second set of electronic components; and a first interface connector physically and electrically coupled to the interface.

In some implementations, the first connector shield includes a first gasket positioned on the first end and compressed against the first surface and the first connector shield includes a second gasket positioned on the second end and compressed against the second surface.

In some implementations, the electronic system assembly of the system comprises a third circuit board including a third set of electronic components; and a second housing containing the third circuit board, the second housing attached to the first housing and enclosing the second circuit board between the first housing and the second housing.

In some implementations, the second circuit board includes a fourth set of electronic components and the electronic system assembly further comprises a second connector shield having second sidewalls defining a second cavity, the second sidewalls having a third end abutting a third surface of the second circuit board and a fourth end abutting a fourth surface of the third circuit board, the third surface opposite to the second surface; and a second electrical connection extending through the second cavity and electrically coupling the third set of electronic components with the fourth set of electronic components.

In some implementations, the electronic system assembly of the system comprises a first port on an exterior of the first housing, the first port electrically coupled to the first set of electronic components; and a second port on an exterior of the second housing, the second port electrically coupled to the third set of electronic components, wherein the first port is electrically coupled to the second port.

In some implementations, the first connector shield of the electronic system assembly includes a flange and one or more apertures extending through the apertures, the first connector shield attached to the first housing via the one or more apertures.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations.

FIG. 1 illustrates a perspective electronic system assembly according to one or more implementations.

FIG. 2 illustrates a partially exploded view of a first subassembly of the electronic system assembly according to one or more implementations.

FIG. 3 illustrates an exploded view of the first subassembly according to one or more implementations.

FIG. 4A illustrates a top perspective view of an example connector shield according to one or more implementations.

FIG. 4B illustrates a bottom perspective view of the example connector shield according to one or more implementations.

FIG. 5A illustrates a plan view of an upper side of a first circuit assembly of the first subassembly according to one or more implementations.

FIG. 5B illustrates a plan view of a lower side of a first circuit assembly of the first subassembly according to one or more implementations.

FIG. 6A illustrates a first side view of the first subassembly according to one or more implementations.

FIG. 6B illustrates a second side view of the first subassembly according to one or more implementations.

FIG. 6C illustrates a cross-sectional view of the first subassembly taken along the line B-B of FIG. 6A according to one or more implementations.

FIG. 6D illustrates a magnified view of a connection between the first circuit assembly and a second circuit assembly of the first subassembly according to one or more implementations.

FIG. 7 illustrates a simplified block diagram of electronic systems associated with the assembly according to one or more implementations.

FIG. 8 illustrates a perspective view of a second electronic system assembly according to one or more implementations.

FIG. 9 illustrates a side view of a circuit subassembly according to one or more implementations.

### DETAILED DESCRIPTION

The present disclosure provides examples of apparatuses, systems, and methods for reducing EMI incident upon sensitive electronics.

The term “set,” as used herein (e.g., a set of keys), refers to a non-empty collection of members. The phrase “coupled to,” as used herein and unless otherwise indicated by the context of the usage, refers to a connection or link between two or more members. Such connection or link may be physical and/or electrical and should be broadly construed to include an indirect connection or link.

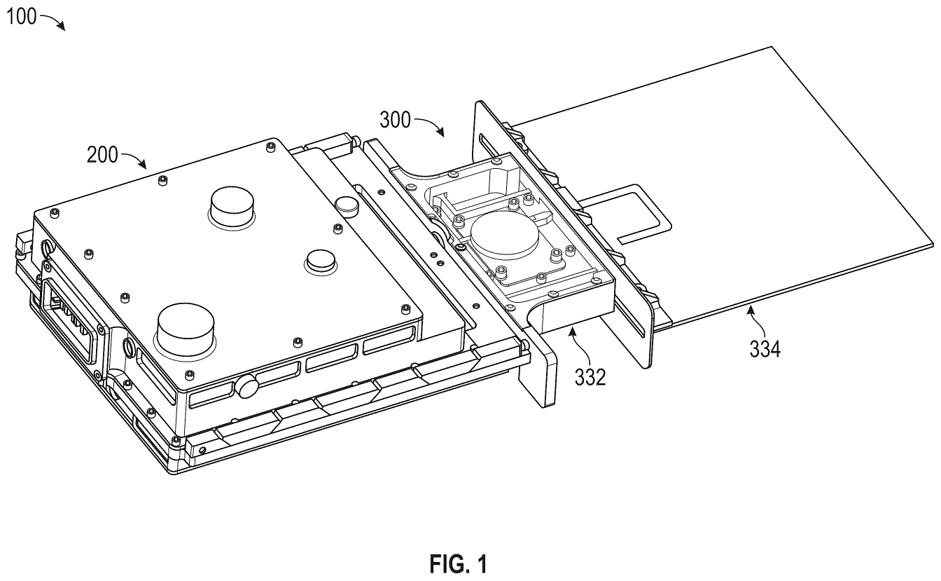

FIG. 1 illustrates a perspective view of an electronic system assembly 100 according to one or more implementations. The assembly 100 includes a first electronic system assembly 200 physically and electrically coupled to a second electronic system assembly 300. The first assembly 200 may include one or more connectors for connecting to one or more other systems, as described herein. The second assembly 300 includes a circuit subassembly 332 physically and electrically coupled to an antenna subassembly 334.

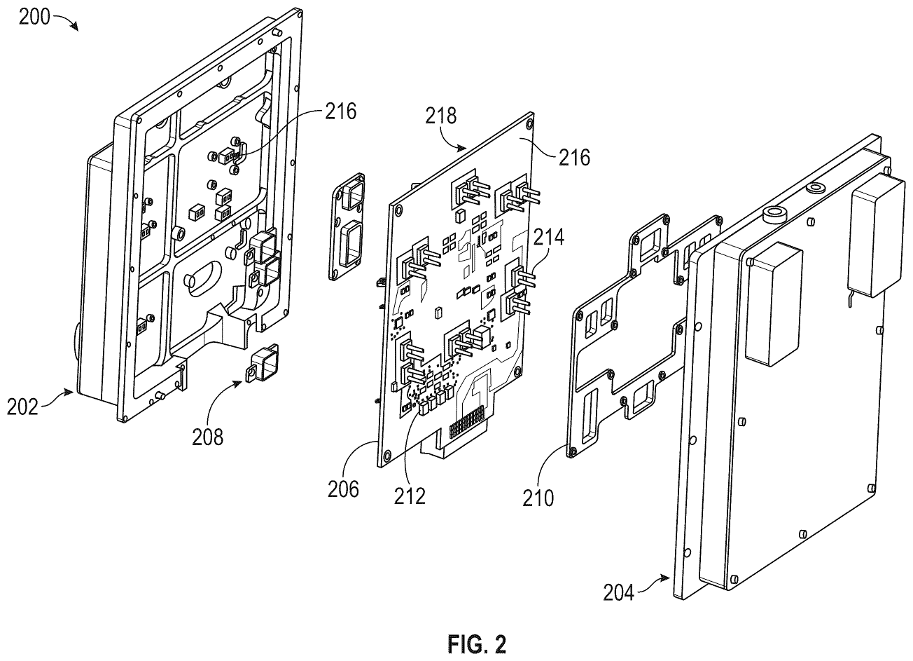

FIG. 2 illustrates a partially exploded view of the first assembly 200 according to one or more implementations. The first assembly 200 includes a first electronic system subassembly 202, a second electronic system subassembly 204, and an electronic first circuit assembly 206. The first assembly 200 also includes a first set of connector shields 208 providing protection for connections between the first circuit assembly 206 and the first subassembly 202. The first assembly 200 also includes a second set of connector shields 210 providing protection for connections between the first circuit assembly 206 and the second subassembly 204.

The first circuit assembly 206 includes a plurality of electronic circuit components 212 that comprise one or more electronic circuits. The first circuit assembly 206 includes a set of connectors 214 for electrically coupling electrical signals between the first circuit assembly 206 and the first subassembly 202 or electrically coupling electrical signals between the first circuit assembly 206 and the second subassembly 204. The connectors 214 may be coupled to and extend from one or more surfaces of the first circuit assembly 206. The first subassembly 202 and/or the second subassembly 204 may include receptacles 217 for receiving the set of connectors 214.

In some implementations, a first side 216 of the first circuit assembly 206 includes a set of the circuit components 212. In some implementations, the first side 216 of the first circuit assembly 206 includes a set of the connectors 214. In some implementations, a second side 218 of the first circuit assembly 206 opposite to the first side 216 includes a set of the circuit components 212. In some implementations, the second side 218 includes a set of the connectors 214. The first subassembly 202 may include sidewalls 220 extending downwardly and defining a recess 222 in which the first circuit assembly 206 may be positioned.

In some implementations, the first assembly 200 may include a lid instead of the second subassembly 206. In such implementations, the lid may attach to the bottom of the sidewalls 220 of the first subassembly 202 and enclose the first circuit assembly 206 within the recess 222.

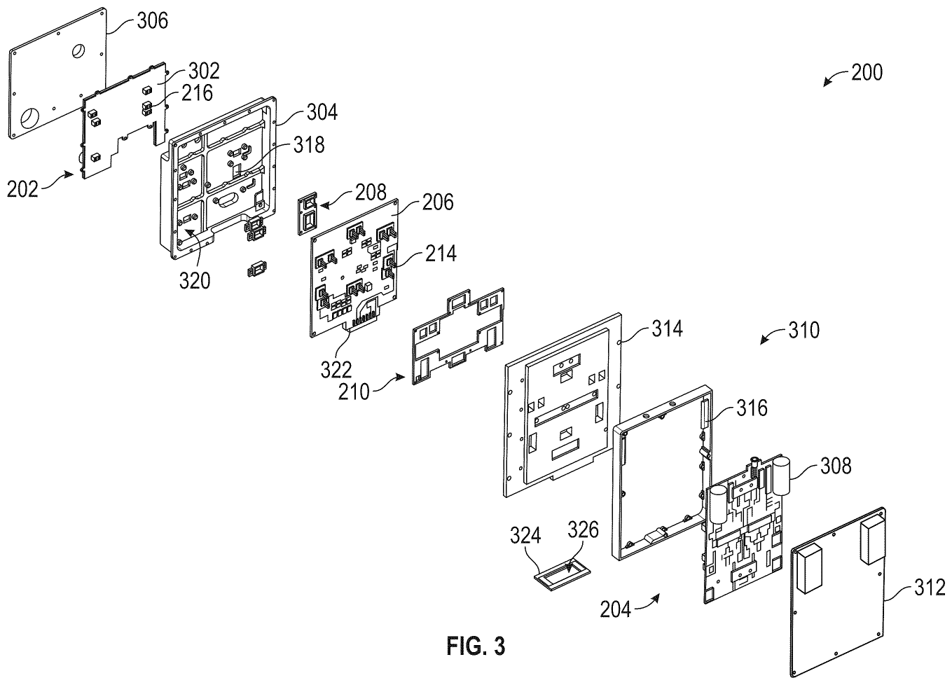

FIG. 3 illustrates an exploded view of the first assembly 200 according to one or more implementations. More particularly, the first subassembly 202 of the first assembly 200 includes a second circuit subassembly 332, a first housing 304, and a first lid 306. The second subassembly 204 of the first assembly 200 includes a third circuit assembly 308, a second housing 310, and a second lid 312. The second housing 310, as shown, includes a base 314 and sidewalls 316. In some implementations, the base 314 and the sidewalls 316 may be a monolithic structure, like the first housing 304, for instance. The base 314 and the sidewalls 316 may collectively form a housing in which the third circuit assembly 308 can be positioned.

When the first subassembly 202 is assembled, the second circuit subassembly 332 can be attached to the first housing 304 and the first lid 306 can be attached to upwardly extending sidewalls of the first housing 304 to enclose the second circuit subassembly 332. When the second subassembly 204 is assembled, the third circuit assembly 308 can be attached to the sidewalls 316 and/or the base 314, the sidewalls 316 are attached to the base 314, and the second lid 312 can be attached to the sidewalls 312 to enclose the third circuit assembly 308. Attachment between various components of the first assembly 200 may be accomplished by mechanical means, such as screws, nuts, bolts, fasteners, and/or rivets, by way of non-limiting example.

The first housing 304 and the second housing 310 include apertures 318 through which the receptacles 217 may protrude to engage with the connectors 214 when the first assembly 200 is assembled. The first housing 304 and the second housing 310 may be comprised of an electrically conductive material, such as aluminum. The first set of connector shields 208 may be attached (e.g., via mechanical means) to a lower side 320 of the first housing 304. When the first set of connector shields 208 are attached, the receptacles 217 of the second circuit subassembly 332 are accessible through apertures in the first set of connector shields 208. The first circuit assembly 206 may then by attached to the lower side 320 with a set of the connectors 214 extending through the connector shields 208 and engaged with the receptacles 217 of the second circuit subassembly 332, thereby electrically coupling circuitry of the first circuit assembly 206 with circuitry of the second circuit subassembly 332. In this configuration, the first set of connector shields 208 are sandwiched between and in contact with the lower surface 320 and an upper surface of the first circuit assembly 206.

The second set of connector shields 210 may be attached to the base 314 and the base 314 may then be attached to the first circuit assembly 206. In this configuration, the second set of connector shields 210 are sandwiched between and in contact with a lower surface of the first circuit assembly 206 and an upper surface of the base 314. The sidewalls 316 and third circuit assembly 308 are attached to the base 314. In this configuration, a set of the connectors 214 extend through apertures in the second set of connector shields 210 and engage with receptacles on the third circuit assembly 308, thereby electrically coupling circuitry of the first circuit assembly 206 with circuitry of the third circuit assembly 308. The second lid 312 may be attached to the sidewalls 316 to enclose the third circuit assembly 308 in the second subassembly 310.

Enclosure of the first and second circuit assemblies 302 and 308 respectively within the first and second subassemblies 202 and 204 reduces the EMI that is incident upon nearby circuitry, such as the first circuit assembly 206. The first circuit assembly 206 may include a connector 322 for electrically coupling with circuitry external to the assembly 100 (see FIG. 1). The second assembly 200 may include a connector shield 324 having an aperture 326 extending therethrough. The connector shield 324 may be coupled to the first or second subassemblies 202 or 204 with the connector 322 extending through the aperture 326. When coupled to an external system via the connector 322, the connector shield 324 reduces EMI coupling via the connector 322.

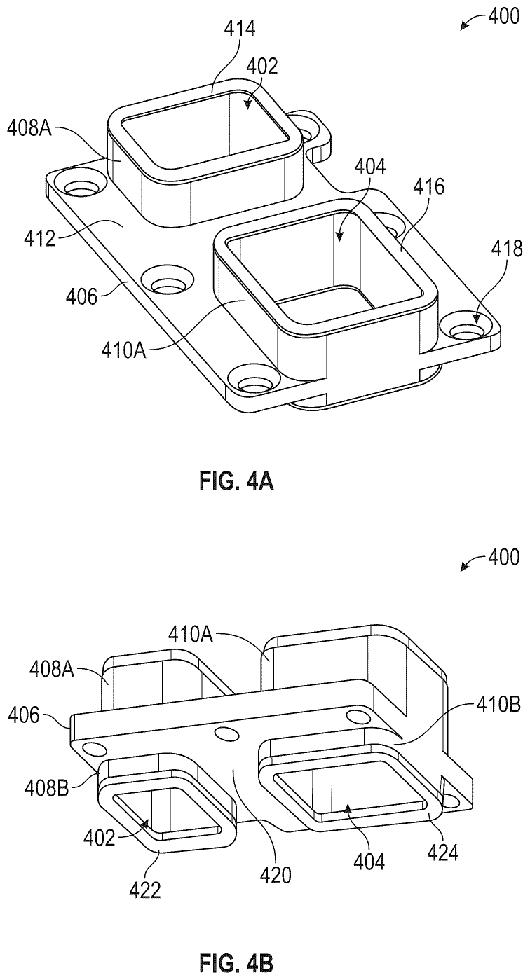

FIG. 4A illustrates a top perspective view of an example connector shield 400 according to one or more implementations. The connector shield 400 corresponds to a connector shield among the first set of connector shields 208; however, those skilled in the art will appreciate that various features of the example connector shield 400 may be modified without departing from the scope of the present disclosure. The connector shield 400 includes shield conduits 402 and 404 through which connectors (e.g., connectors 214 of FIG. 2) may extend to electrically couple circuitry of different circuit assemblies. The connector shield 400 also includes a flange 406 extending transversely from the shield conduits 402 and 404.

The connector shield 400 includes sidewalls 408A extending upwardly from an upper surface 412 of the flange 406. The connector shield 400 also includes sidewalls 410A extending upwardly from the upper surface 412 of the flange 406. The sidewalls 408A are spaced apart from the sidewalls 410A along the flange 406. A first gasket 414 can be provided on an upper end of the sidewalls 408A and a second gasket 416 can be provided on an upper end of the sidewalls 410A. In some implementations, the first gasket 414 and/or the second gasket 416 are comprised of an elastically deformable material, such as rubber, silicone, or neoprene, by way of non-limiting example. In some implementations, the first gasket 414 and/or the second gasket 416 are form-in-place gaskets comprised of an electrically conductive material suspended in a base material. For instance, the first gasket 414 and/or the second gasket 416 may include conductive flakes or particulate (e.g., of nickel, aluminum, or silver) suspended in a silicone or synthetic rubber. The connector shield 400 further includes a plurality of apertures 418 for receiving mechanical connectors, such as screws, fasteners, bolts, or rivets, also by way of non-limiting example.

FIG. 4B illustrates a bottom perspective view of the example connector shield 400 according to one or more implementations. The connector shield 400 includes sidewalls 408B extending downwardly from a lower surface 420 of the flange 406. The connector shield 400 also includes sidewalls 410B extending downwardly from the lower surface 420. A third gasket 422 can be provided on a lower end of the sidewalls 408B and a fourth gasket 424 can be provided on a lower end of the sidewalls 410B. In some implementations, the third gasket 422 and/or the fourth gasket 420 are comprised of an elastically deformable material, such as rubber, silicone, or neoprene, by way of non-limiting example. In some implementations, the third gasket 422 and/or the fourth gasket 424 are form-in-place gaskets comprised of an electrically conductive material suspended in a base material, as discussed with respect to the first and second gaskets 414 and 416.

The sidewalls 408A and 408B (collectively “sidewalls 408”) extend continuously to define the shield conduit 402. The sidewalls 410A and 410B (collectively “sidewalls 410”) extend continuously to define the shield conduit 404. In some implementations, the sidewalls 408, the sidewalls 410, and the flange 406 are a monolithic member formed of an electrically conductive material, such as aluminum or copper.

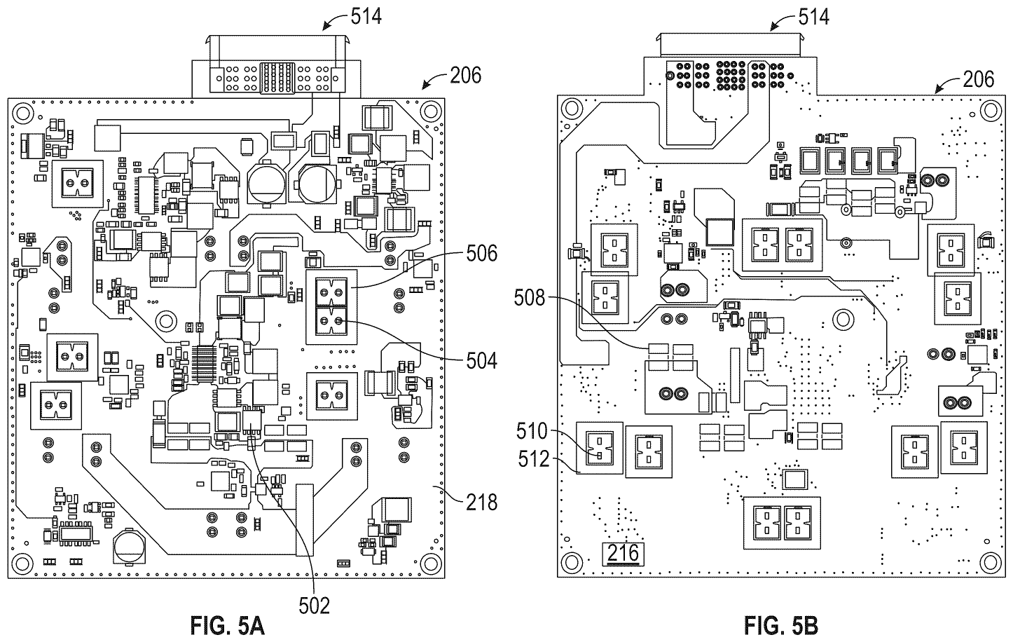

FIG. 5A illustrates a plan view of the upper side 218 of the first circuit assembly 206 according to one or more implementations. The first circuit assembly 206 includes a plurality of circuit components 502 provided on the upper side 218. The first circuit assembly 206 further includes a plurality of connectors 504 extending upwardly from the upper side 218. The first circuit assembly 206 includes a plurality of connector contacts 506 that each surround one of the connectors 504 on the upper side 218. At least some of the connector contacts 506 may be coupled to the same node or point in a circuit—for instance, a set of the connector contacts 506 may be connected to a ground node in a circuit. In some implementations, the connectors 504 are conductive pins or prongs.

FIG. 5B illustrates a plan view of the lower side 216 of the first circuit assembly 206 according to one or more implementations. The first circuit assembly 206 includes a plurality of circuit components 508 provided on the lower side 216. The first circuit assembly 206 further includes a plurality of connectors 510 extending downwardly from the lower side 216. In some implementations, the connectors 510 are conductive pins or prongs. The first circuit assembly 206 includes a plurality of connector contacts 512 that each surround one of the connectors 510 on the lower side 216. At least some of the connector contacts 512 may be coupled to the same node or point in a circuit—for instance, a set of the connector contacts 506 may be connected to a ground node in a circuit.

The first circuit assembly 206 includes a connector 514 provided on an edge for electrically coupling the first circuit assembly 206 to one or more external systems. Electrical signals received via the connector 514 may be conditioned, converted, amplified, etc., by the circuit components 502 and/or 508. Sets of the circuit components 502 and/or 508 are configured and interconnected (e.g., via traces in the printed circuit board) to perform various operations involving the electrical signals received. The first circuit assembly 206 may be configured to provide output to the second circuit subassembly 332 and/or the third circuit assembly 308 (see FIG. 3) via the connectors 504 and/or 510.

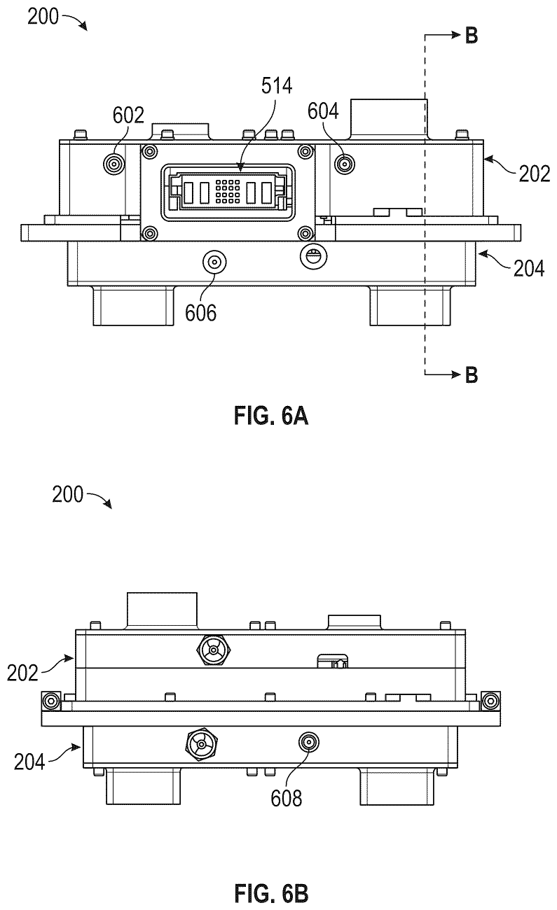

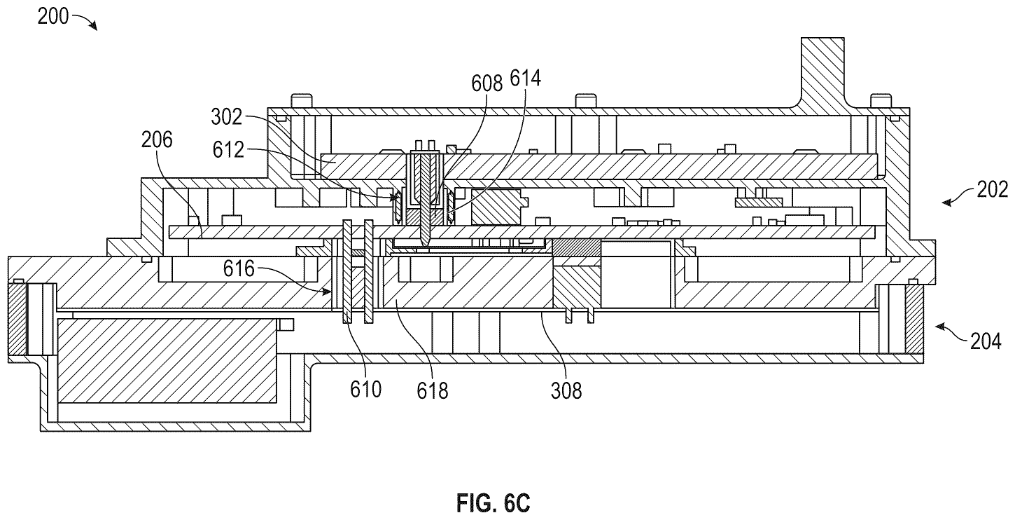

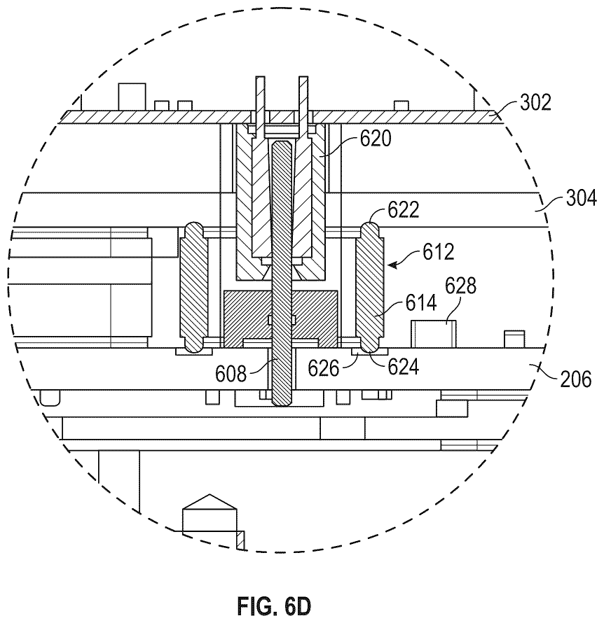

FIG. 6A shows a first side view of the first assembly 200 according to one or more implementations. The first assembly 200 includes a first port 602 and a second port 604 provided on a side of the first subassembly 202. The first assembly 200 also includes a third port 606 provided on a side of the second subassembly 204. The connector 514 (see FIG. 5) can be provided on a side of the first assembly 202. The first port 602, the second port 604, and/or the third port 606 may be for coupling a certain type of electronic signal—for instance, coaxial connectors for conveying a radio frequency (RF) signal.

FIG. 6B shows a second side view of the first assembly 200 according to one or more implementations. The first assembly 200 includes a fourth port 608 provided on a side of the second subassembly 204.

FIG. 6C shows a cross-sectional view of the first assembly 200 taken along the line B-B of FIG. 6A according to one or more implementations. A first set of connectors 608 electrically couples the second circuit subassembly 332 of the first subassembly 202 with the first circuit assembly 206. A second set of connectors 610 electrically couples the third circuit assembly 308 of the second subassembly 204 with the first circuit assembly 206. The first set of connectors 608 correspond to the connectors 504 (see FIG. 5A) and the second set of connectors 610 correspond to the connectors 510 (see FIG. 5B).

In some implementations, the connectors 608 and the connectors 610 are pins or prongs that are engaged with corresponding receptacles on the second circuit assembly 302 and the third circuit assembly 308, respectively. In some implementations, the connectors 608 and/or the connectors 610 are wires that are engaged with corresponding receptacles on the second circuit assembly 302 and the third circuit assembly 308, respectively.

The first assembly 200 includes a connector shield 612 having sidewalls 614 defining a cavity through which the first set of connectors 608 extend to electrically couple the first circuit assembly 206 and the second circuit subassembly 332. The first assembly 200 also includes a connector shield 616 having sidewalls 618 defining a cavity through which the second set of connectors 610 extend to electrically couple the first circuit assembly 206 and the third circuit assembly 308. The sidewalls 614 and 618 reduce electromagnetic radiation emitted by the first and second connectors 608 and 610 or generated by the second circuit subassembly 332, the third circuit assembly 308, and/or the first circuit assembly 206. Accordingly, the sidewalls 614 and 618 reduce EMI that could affect the second circuit subassembly 332, the third circuit assembly 308, and/or the first circuit assembly 206.

The first housing 304 can be attached with the base 314 to enclose the first circuit assembly 206 within the first electronic system assembly 200. The sidewalls 220 of the first housing 304 define a cavity 620 in which the first circuit assembly 202 can be housed. The first circuit assembly 206 may be mechanically attached (e.g., via screws, bolts, rivets) to the base 314 of the second subassembly 204.

FIG. 6D shows a magnified view of a connection between the first circuit assembly 206 and the second circuit assembly 302 according to one or more implementations. The connector 608 extends upwardly from a circuit board of the first circuit assembly 206. The connector 608 can be engaged with a receptacle 620 of the second circuit assembly 302. The connector shield 612 can be attached to the housing 304 of the first subassembly 202 via connecting means extending through apertures of the connector shield 612 (see apertures 418 of FIG. 4).

Upper ends 622 of the sidewalls 614 include a gasket (see gaskets 422, 424 of FIG. 4) that can be in contact with and compressed against a surface of the housing 304. Lower ends 624 of the sidewalls 614 include a gasket (see gaskets 414, 416 of FIG. 4) that can be in contact with and compressed against a surface of a circuit board of the first circuit assembly 206. The lower ends 624 contact a connector contact 626 of the plurality of connector contacts 506 (see FIG. 5A). The connector contact 626 can be coupled to a ground or ground plane of the first circuit assembly 206. The ground can be coupled to one or more circuit components 628 of the first circuit assembly 206.

In some implementations, the connector shield 612 can be monolithically formed with the housing 304 of the first subassembly 202. The shield connector 616 can be configured and connected between the first circuit assembly 206 and the second subassembly 204 so further description thereof is omitted for brevity.

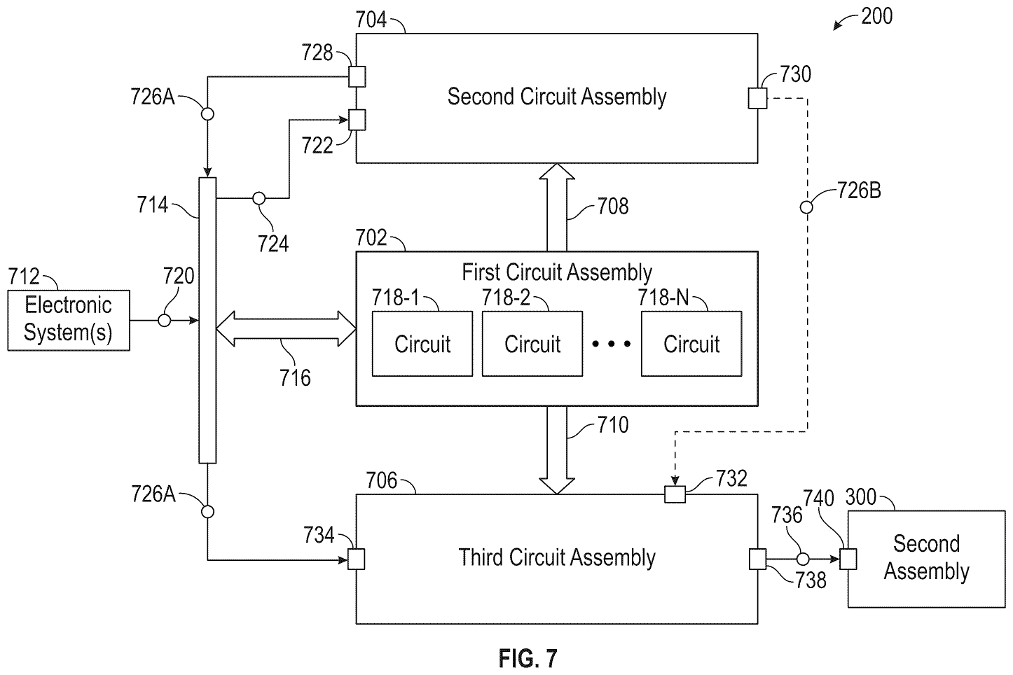

FIG. 7 illustrates a simplified block diagram of electronic systems associated with the assembly 100 according to one or more implementations. The assembly 100 includes a first circuit assembly 702, a second circuit assembly 704, and a third circuit assembly 706. The first circuit assembly 702 corresponds to the first circuit assembly 206, the second circuit assembly 704 corresponds to the second circuit subassembly 332, and the third circuit assembly corresponds to the third circuit assembly 308. The first circuit assembly

The first circuit assembly 702 can be electrically coupled to the second circuit assembly 704 via a set of connectors 708 provided on the upper side 218 of the first circuit assembly 702 (see, e.g., FIG. 3). The first circuit assembly 702 can be electrically coupled to the third circuit assembly 704 via a set of connectors 710 provided on the lower side 216 of the first circuit assembly 702 (see, e.g., FIG. 3). One or more electronic systems 712 may be electrically coupled to the first circuit assembly 702 via an interface 714. The first circuit assembly 702 may be electrically coupled to the interface 714 via a third set of connectors 716. The interface 714 may be a backplane system including connectors for coupling to a plurality of circuit assemblies, including the first circuit assembly 702, the second circuit assembly 704, and/or the third circuit assembly 706.

The first circuit assembly 702 may include a set of circuits 718-1, 718-2, . . . 718-N (collectively “circuits 718”) configured to generate one or more electrical signals provided to the second circuit assembly 704 via the set of connectors 708 and/or the third circuit assembly 706 via the set of connectors 706. The circuits 718 may include one or more power converters configured to convert one or more power signals provided from the electronic system(s) 712. For instance, the one or more power converters of the circuits 718 may include a first power converter (e.g., buck converter, boost converter) configured to convert a first power provided by the electronic system(s) 712 into a second power conveyed to the second circuit assembly 704. As another example, the one or more power converters of the circuits 718 may include a second power converter (e.g., buck converter, boost converter) configured to convert a third power provided by the electronic system(s) 712 into a fourth signal conveyed to the third circuit assembly 706.

The circuits 718 may include one or more bias power circuits configured to convert an input voltage (e.g., 5 Vdc, 10 Vdc) into one or more gate biasing voltages for biasing one or more power amplifiers of the second circuit assembly 704 and/or biasing one or more power amplifiers of the third circuit assembly 706. The circuits 718 may bias the power amplifiers of the second circuit assembly 704 and/or the third circuit assembly 706.

The electronic system(s) 712 may include a radio frequency (RF) generator configured to generate an RF signal in a defined frequency range. The defined frequency range may be between 0.25 GHz and 4 GHz, inclusive, by way of non-limiting example. The electronic system(s) 712 may include control systems configured to generate control signals for operating one or more of the circuit assemblies of the assembly 200. The electronic system(s) 712 has one or more outputs electrically coupled to provide one or more electric signals 720 to the interface 714. The one or more electric signals 720 may include the aforementioned RF signal. The electronic system(s) 712 are coupled to the second circuit assembly 704 via the interface 714. The interface 714 may be coupled to an input port 722 of the second circuit assembly 704 to which an RF signal 724 included in the one or more electric signals 720. The input port 722 may be a coaxial connector in some implementations.

The second circuit assembly 704 may be configured to perform one or more circuit functions involving an electrical input provided by the electronic system(s) 712 and/or the first circuit assembly 702. The second circuit assembly 704 may include driver amplifier circuitry configured to drive or control operation of another circuit of the third circuit assembly 706. As a more specific but non-limiting example, the second circuit assembly 704 may include a driver amplifier that generates a RF input signal 726A having one or more waveform characteristics matching one or more waveform characteristics of the RF signal 724. For instance, the RF input signal 726A may have a pulse width, a duty cycle, and/or a frequency corresponding or matching a pulse width, a duty cycle, and/or a frequency of the RF signal 724.

The RF input signal 726A may be emitted via an output port 728 of the second circuit assembly 704, which can be electrically coupled to the interface 714. The output port 728 may be a coaxial connector or other similar hardware connection suitable for conveying a signal in the RF range. In some implementations, an output port 730 of the second circuit assembly 704 may be directly coupled to an input port 732 of the third circuit assembly 730. The gate driver circuitry of the second circuit assembly 704 may generate a RF input signal 726B (that can be substantially similar to the RF input signal 726A) which can be directly provided to the third circuit assembly 706 via a hardwired connection, such as a coaxial cable.

An input port 734 of the third circuit assembly 706 may be coupled to the interface 714. The input port 734 may be a port suitable for conveying an RF signal, such as a coaxial port. In such implementations, the RF input signal 726A can be conveyed from the output port 728, through the interface 714, and into the third circuit assembly 706 via the input port.

The third circuit assembly 706 may be configured to perform one or more circuit functions involving an electrical input provided by the electronic system(s) 712, the first circuit assembly 702, and/or the second circuit assembly 704. The third circuit assembly 706 may include RF power amplifier circuitry configured to convert a first RF signal having a first amplitude into a second RF signal having a second amplitude higher than the first amplitude. As a specific yet non-limiting example, the RF power amplifier circuitry may generate an RF output signal 736 based on the RF input signal 726A/726B. The RF input signal 726A/726B may be provided to first terminal(s) (e.g., gate terminal(s)) of the amplifier circuitry of the third circuit assembly 706. The first circuit assembly 702 may provide a gate bias power signal to the first terminal(s) of the amplifier circuitry. The first circuit assembly 702 may provide a supply voltage (e.g., drain-to-source voltage) to second terminal(s) of the amplifier circuitry of the third circuit assembly 706.

In some implementations, a power level at which the second circuit assembly 704 or the third circuit assembly 706 operates may be an order of magnitude greater than a power level at which the circuits 718 of the first circuit assembly 702 operate. In some implementations, a frequency at which the second circuit assembly 704 or the third circuit assembly 706 operates may be higher than a frequency at which the circuits 718 of the first circuit assembly 702 operate.

An output port 738 of the third circuit assembly 706 can be electrically and/or physically coupled to an input port 740 of the to the second electronic system assembly 300. The output port 738 and the input port 740 are ports suitable for conveying an RF signal, such as a coaxial port. The RF output signal 736 can be conveyed to the second electronic system assembly 300 through the input port 740.

The second circuit assembly 704 and/or the third circuit assembly 706 include circuitry that operates at higher power levels and at higher frequency than the circuitry 718 of the first circuit assembly 702. The connector shields described herein (e.g., connector shields 208, 210, 400, 612, 616) shield the connectors 708 and 710. As a result, EMI may not be coupled from the second circuit assembly 704 and/or the third circuit assembly 706 into the first circuit assembly 702 via the connectors 708 and 710.

In some implementations, a plurality of electronic system assemblies 100—each comprising at least the first subassembly 200—are coupled to the interface 714. In such implementations, the electronic system(s) 712 may send electronic signals (e.g., RF signals, power signals) to the plurality of electronic system assemblies 100. The plurality of electronic system assemblies 100 may be arranged in rows and columns. The second subassemblies 300 may be spaced apart according to a wavelength of an RF signal provided by the electronic system(s) 712.

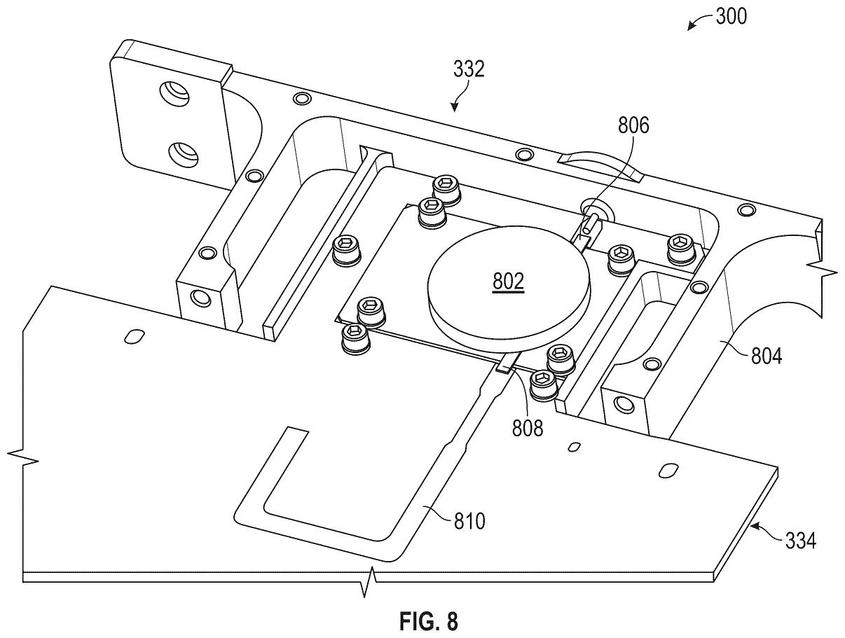

FIG. 8 illustrates a perspective view of the second electronic system assembly 300 according to one or more implementations. When fully assembled, the circuit subassembly 332 of the second assembly 300 may include a lid, which is removed in the perspective view of FIG. 8 for clarity. The circuit subassembly 332 includes a set of circuit components 802 contained within a housing 804. In some implementations, the set of circuit components 802 may include an RF circulator configured to regulate the flow of an RF signal between ports or terminals thereof.

A first conductor 806 can be electrically coupled to the input port 740 of the second assembly 300. The first conductor 806 can be also electrically coupled to a first terminal of the circuit component(s) 802. A second conductor 808 can be electrically coupled to a second terminal of the circuit component(s) 802. The second conductor 808 can be also electrically coupled to an antenna element 810 of the antenna subassembly 334. The first and second conductors 806 and 808 are conductive traces, strips, or feedlines (e.g., of copper) disposed on a surface of a circuit board within the housing 804.

During operation of the electronic system assembly 100, the third circuit assembly 706 outputs a high-powered RF signal (e.g., exceeding 1 kW), which can be conveyed into the input port 740 of the second electronic system assembly 300 and through the first conductor 806 to the electronic component(s) 802. The RF signal travels through the circuit component(s) 802, then through the second conductor 808, and to the antenna element 810. Under some conditions, the high power level of the RF signal flowing through the first and second conductors 806 and 808 may cause electrical arcing and/or generate plasma, which can damage hardware, such as the circuit component(s) 802, the first conductor 806, and/or the second conductor 808.

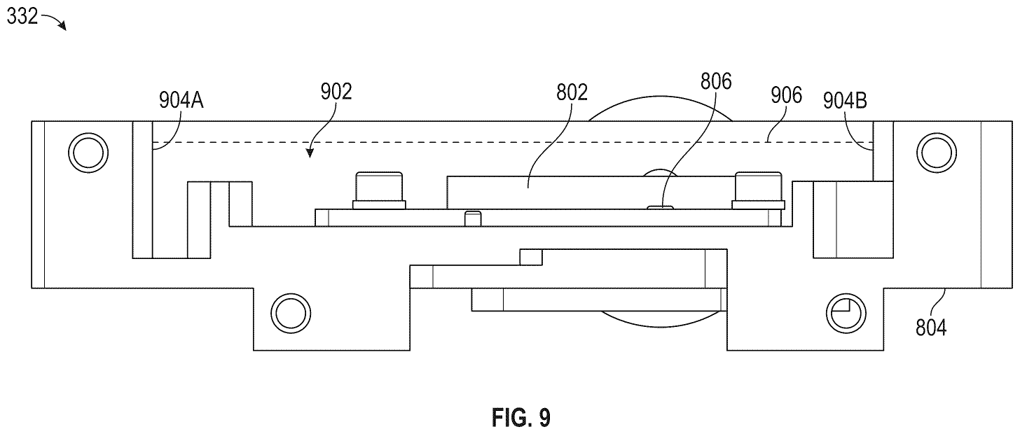

FIG. 9 illustrates a side view of the circuit subassembly 332 according to one or more implementations. The circuit subassembly 332 includes an electrically insulating material 902 contained within the housing 804. The housing 804 includes sidewalls 904A and 904B extending upwardly and defining a cavity in which the electronic component(s) 802 and the first and second conductors 804 and 806 are positioned. The insulating material 902 can be a material with a low dielectric constant and loss. The insulating material 902 is, in some implementations, a silicone or a silicone rubber. In some implementations, the insulating material 902 can be a room-temperature vulcanizing (RTV) silicone. In some implementations, the insulating material 902 can be a dielectric epoxy. The insulating material 902 may have a dielectric constant having the same order of magnitude as air.

The insulating material 902 can be filled to a level 906 completely covering the first and second conductors 804 and 806. In some implementations, the insulating material 902 can be filled to a level 906 covering the electrical component(s) 802. As a result of the insulating material 902, electrical arcing and/or generation of plasma within the housing 804 can be reduced or prevented.

### Other Variations

Features, materials, characteristics, or groups described in conjunction with a particular aspect, embodiment, or example are to be understood to be applicable to any other aspect, embodiment or example described herein unless incompatible therewith. All the features disclosed in this specification (including any accompanying claims, abstract and drawings), and/or all the steps of any method or process so disclosed, may be combined in any combination, except combinations where at least some of such features and/or steps are mutually exclusive. The protection is not restricted to the details of any foregoing implementations. The protection extends to any novel one, or any novel combination, of the features disclosed in this specification (including any accompanying claims, abstract and drawings), or to any novel one, or any novel combination, of the steps of any method or process so disclosed.

While certain implementations have been described, these implementations have been presented by way of example only and are not intended to limit the scope of protection. Indeed, the novel methods and systems described herein may be embodied in a variety of other forms. Furthermore, various omissions, substitutions, and changes in the form of the methods and systems described herein may be made. Those skilled in the art will appreciate that in some implementations, the actual steps taken in the processes disclosed and/or illustrated may differ from those shown in the figures. Depending on the embodiment, certain of the steps described above may be removed, others may be added. For example, the actual steps and/or order of steps taken in the disclosed processes may differ from those described and/ore shown in the figure. Depending on the embodiment, certain of the steps described above may be removed, others may be added. For instance, the various components illustrated in the figures and/or described may be implemented as software and/or firmware on a processor, controller, ASIC, FPGA, and/or dedicated hardware. Furthermore, the features and attributes of the specific implementations disclosed above may be combined in different ways to form additional implementations, all of which fall within the scope of the present disclosure.

In some cases, there is provided a non-transitory computer readable medium storing instructions, which when executed by at least one computing or processing device, cause performing any of the methods as generally shown or described herein and equivalents thereof.

Any of the memory components described herein can include volatile memory, such random-access memory (RAM), dynamic random-access memory (DRAM), synchronous dynamic random-access memory (SDRAM), double data rate (DDR) memory, static random-access memory (SRAM), other volatile memory, or any combination thereof. Any of the memory components described herein can include non-volatile memory, such as magnetic storage, flash integrated circuits, read only memory (ROM), Chalcogenide random access memory (C-RAM), Phase Change Memory (PC-RAM or PRAM), Programmable Metallization Cell RAM (PMC-RAM or PMCm), Ovonic Unified Memory (OUM), Resistance RAM (RRAM), NAND memory (e.g., single-level cell (SLC) memory, multi-level cell (MLC) memory, or any combination thereof), NOR memory, EEPROM, Ferroelectric Memory (FeRAM), Magnetoresistive RAM (MRAM), other discrete NVM (non-volatile memory) chips, or any combination thereof.

Any user interface screens illustrated and described herein can include additional and/or alternative components. These components can include menus, lists, buttons, text boxes, labels, radio buttons, scroll bars, sliders, checkboxes, combo boxes, status bars, dialog boxes, windows, and the like. User interface screens can include additional and/or alternative information. Components can be arranged, grouped, displayed in any suitable order.

Conditional language used herein, such as, among others, “can,” “could,” “might,” “may,” “e.g.,” and the like, unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Disjunctive language such as the phrase “at least one of X, Y, Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain implementations require at least one of X, at least one of Y, or at least one of Z to each be present.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, or within less than 0.01% of the stated amount.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations.

The foregoing description, for purposes of explanation, used specific nomenclature to provide a thorough understanding of the disclosure. However, it will be apparent to one skilled in the art that specific details are not required in order to practice the disclosed implementations. Thus, the foregoing descriptions of specific implementations are presented for purposes of illustration and description. They are not intended to be exhaustive or to limit the disclosure to the precise forms disclosed; obviously, many modifications and variations are possible in view of the above teachings. The implementations were chosen and described in order to best explain the principles of the disclosure and its practical applications, they thereby enable others skilled in the art to best utilize the disclosure and various implementations with various modifications as are suited to the particular use contemplated. It is intended that the claims as presented herein or as presented in the future and their equivalents define the scope of the protection.

1. An electronic system assembly, comprising:
a first circuit board including a first set of electronic components;
a first housing containing the first circuit board;
a second circuit board including a second set of electronic components;
a first connector shield having first sidewalls defining a first cavity, the first sidewalls having a first end abutting a first surface of the first circuit board and a second end abutting a second surface of the second circuit board; and
a first electrical connection extending through the first cavity and electrically coupling the first set of electronic components with the second set of electronic components.

2. The electronic system assembly of claim 1, wherein the first connector shield includes a first gasket positioned on the first end and compressed against the first surface and a second gasket positioned on the second end and compressed against the second surface.

3. The electronic system assembly of claim 2, wherein the first gasket and the second gasket include an elastically deformable material and an electrically conductive material.

4. The electronic system assembly of claim 1, wherein the first electrical connection includes a set of pins engaged with a set of receptacles.

5. The electronic system assembly of claim 1, wherein the first set of electronic components are part of a first circuit on the first circuit board and the second set of electronic components are part of a second circuit on the second circuit board, and wherein the first circuit operates at a first power level and the second circuit operates at a second power level lower than the first power level, the first connector shield reducing electromagnetic interference coupling from the first circuit into the second circuit.

6. The electronic system assembly of claim 5, wherein the first circuit is a Radio Frequency circuit and the second circuit is a power converter circuit.

7. The electronic system assembly of claim 1, wherein the first connector shield includes a flange and one or more apertures extending through the one or more apertures, the first connector shield attached to the first housing via the one or more apertures.

8. The electronic system assembly of claim 1, further comprising:
a third circuit board including a third set of electronic components; and
a second housing containing the third circuit board, the second housing attached to the first housing and enclosing the second circuit board between the first housing and the second housing.

9. The electronic system assembly of claim 8, wherein the second circuit board includes a fourth set of electronic components, the electronic system assembly further comprising:
a second connector shield having second sidewalls defining a second cavity, the second sidewalls having a third end abutting a third surface of the second circuit board and a fourth end abutting a fourth surface of the third circuit board, the third surface opposite to the second surface; and
a second electrical connection extending through the second cavity and electrically coupling the third set of electronic components with the fourth set of electronic components.

10. The electronic system assembly of claim 9, wherein the second connector shield includes a third gasket positioned on the third end and compressed against the third surface and the second connector shield including a fourth gasket positioned on the fourth end and compressed against the fourth surface.

11. The electronic system assembly of claim 8, wherein the second circuit board includes an electrical connector exposed on an exterior of the electronic system assembly between the first housing and the second housing.

12. The electronic system assembly of claim 1, further comprising:
a first port exposed on an exterior of the first housing, the first port electrically coupled to the first set of electronic components;
a second housing having a bottom surface and sidewalls extending upwardly from the bottom surface;
a second port exposed on an exterior of the second housing, the second port electrically coupled to the first port;
a third circuit board attached to the bottom surface, the third circuit board including an electronic component and a first conductor on a surface of the third circuit board, the first conductor electrically coupled to the electronic component and the second port; and
an electrically insulating material completely covering the first conductor.

13. The electronic system assembly of claim 12, wherein the electrically insulating material includes a silicone.

14. The electronic system assembly of claim 12, wherein the electrically insulating material at least partially covers the electronic component.

15. A system, comprising:
an electronic system configured to generate a set of electronic signals;
an interface including a plurality of connectors arranged along a surface of the interface, the interface electrically coupled to the electronic system; and
an electronic system assembly, comprising:
a first circuit board including a first set of electronic components;
a first housing containing the first circuit board;
a second circuit board including a second set of electronic components;
a first connector shield having first sidewalls defining a first cavity, the first sidewalls having a first end abutting a first surface of the first circuit board and a second end abutting a second surface of the second circuit board;
a first electrical connection extending through the first cavity and electrically coupling the first set of electronic components with the second set of electronic components; and
a first interface connector physically and electrically coupled to the interface.

16. The system of claim 15, wherein the first connector shield includes a first gasket positioned on the first end and compressed against the first surface and the first connector shield includes a second gasket positioned on the second end and compressed against the second surface.

17. The system of claim 15, wherein the electronic system assembly further comprises:
a third circuit board including a third set of electronic components; and
a second housing containing the third circuit board, the second housing attached to the first housing and enclosing the second circuit board between the first housing and the second housing.

18. The system of claim 17, wherein the second circuit board includes a fourth set of electronic components, the electronic system assembly further comprising:
a second connector shield having second sidewalls defining a second cavity, the second sidewalls having a third end abutting a third surface of the second circuit board and a fourth end abutting a fourth surface of the third circuit board, the third surface opposite to the second surface; and
a second electrical connection extending through the second cavity and electrically coupling the third set of electronic components with the fourth set of electronic components.

19. The system of claim 17, wherein the electronic system assembly further comprises:
a first port on an exterior of the first housing, the first port electrically coupled to the first set of electronic components; and
a second port on an exterior of the second housing, the second port electrically coupled to the third set of electronic components, wherein the first port is electrically coupled to the second port.

20. The system of claim 15, wherein the first connector shield includes a flange and one or more apertures extending through the one or more apertures, the first connector shield attached to the first housing via the one or more apertures.
